(19) United States
(12) Patent Application Publication
(10) Pub. No.: US 2010/0142265 A1
(43) Pub. Date: Jun. 10, 2010

(54) MAGNETIC STRUCTURE WITH MULTIPLE-BIT STORAGE CAPABILITIES

(76) Inventors: Derek Atkinson, County Durham (GB); David Samuel Eastwood, Sowerby Bridge (GB)

Correspondence Address: Zilka-Kotab, PC, P.O. BOX 721120, SAN JOSE, CA, 95172-1120, US

(21) Appl. No.: 12/523,953

(22) PCT Filed: Jan. 2, 2008
(86) PCT No.: PCT/GB08/00004

§ 371 Date: Jan. 12, 2010

(30) Foreign Application Priority Data
Jan. 27, 2007 (GB) 0701570.4

(51) Int. Cl. G11C 11/14; G11C 7/00; H01L 21/8246

(52) U.S. Cl. 365/171; 365/189.011; 438/3; 257/E21.665

(57) ABSTRACT

A magnetic structure (2) comprising a magnetic layer (18) having an upper surface and a lower surface is disclosed. The magnetic layer comprises a plurality of regions, each of which is adapted to be magnetised predominantly along a first or second direction. The magnetic layer further comprises at least one structured feature (21) adapted to prevent passage of a magnetic domain wall (26) of a respective type and at least one second structural feature (22) adapted to prevent propagation of at least one magnetic domain wall (34) of a second type. A data storage device (46) incorporating the magnetic structure is also disclosed.

### FIELD OF THE INVENTION

The present invention generally relates to magnetic structures having structural features adapted to impede propagation of magnetic domain walls, and relates particularly, but not exclusively, to memory storage devices including such magnetic structures.

### BACKGROUND OF THE INVENTION

Two commonly used data storage methods are (i) magnetic disk drives and (ii) dynamic random access memory (DRAM). Disk drives are capable of inexpensively storing large amounts of data, i.e. greater than 100 GB, but can be unreliable and relatively slow. Dynamic random access memory (DRAM), on the other hand, typically based on solid-state technology, currently stores data in the range of 1 GB, is relatively expensive and needs to be frequently refreshed in order to retain stored data.

Magnetoresistive random access memory (MRAM) is an attempt to overcome some of the above disadvantages of existing memory storage techniques, and uses nanomagnets and spintronics in the form of a new type of solid-state magnetic memory technology. MRAM combines the high memory density of DRAM, the data input/output speed of SRAM, the non-volatile capability of FLASH memory without the need for external power to maintain the memory state and has unlimited re-write capabilities. This combination provides new possibilities for electronic technology such as ‘instant on’ computers.

MRAM devices store data in the form of the direction along which magnetic moment is aligned in a ferromagnetic material. Atomic magnetic moments in ferromagnetic materials respond to applied magnetic fields, aligning their magnetic moments to the direction of the applied magnetic field. When the applied field is removed, the magnetic moments still remain aligned in the direction of the previously applied magnetic field. A magnetic field applied in the opposite direction then causes the, atoms to reverse their magnetic moments and realign themselves along the direction of the newly applied field. As the direction of the magnetic moments in the magnetic material reverses, the material forms respective regions of reversed and unreversed magnetic moments (known as magnetic domains), separated by a magnetic domain wall, which then propagates along the magnetic material until the direction of alignment of substantially all of the magnetic moments in the magnetic material has become reversed. Magnetic domain walls can be distinguished by their type such as, for example, their chirality, which can be one of two different states.

FIG. 1 shows an example of a known MRAM cell 1 which uses a magnetic tunnelling junction comprising two ferromagnetic layers, known as a “free layer” 2 and a “reference layer” 4, separated by a thin dielectric layer 6. The magnetic layers 2, 4 are sufficiently thin to provide single magnetic domains with substantially uniform magnetisation direction. Digital data, i.e. ‘ones’ and ‘zeros’, is stored by means of orientation of the magnetic moment 8 of the ‘free layer’ 2. The orientation of the magnetic moment 10 of the “reference layer” is fixed. The magnetic moment 8 of the ‘free layer’ 2 can be selectively oriented parallel or anti-parallel to that of the ‘reference layer’ 4, by application of a suitable magnetic field.

The applied magnetic fields are generated, for example, by current flow through electrodes in the form of a conducting wire 12 provided in close proximity to the ‘free layer’ 2. The stored data is read-out by measuring the electrical resistance 14 between the first electrode 12, coupled to the ‘free layer’ 2, and a second electrode 16, coupled to the ‘reference layer’ 4. The electrical resistance 14 through the MRAM cell 1 varies in dependence upon the magnetic orientation of the ‘free layer’ 2 relative to that of the ‘reference layer’ 4. For example, the electrical resistance 14 is low when the magnetic orientation within the ‘free layer’ 2 is parallel to the magnetic moment of the ‘reference layer’ 4, and is high when the magnetic orientations are opposite to each other. The binary data values are therefore represented by high and low values of the electrical resistance between the electrodes 12, 16.

However, because each MRAM cell can only store one bit of data (‘0’ or ‘1’), the maximum possible memory capacity is limited. Current available MRAM memory is in the range of 1 Mb and is much less than needed for many memory applications.

### SUMMARY OF THE INVENTION

Preferred embodiments of the present invention seek to overcome one or more of the above disadvantages of the prior art.

According to an aspect of the present invention, there is provided a magnetic structure comprising at least one magnetic layer adapted to be magnetised such that said layer includes (i) a respective plurality of regions, wherein the regions of each pair of adjacent said regions of said layer are magnetised predominantly along opposite directions and are separated by a respective magnetic domain wall, and (ii) at least one first structural feature adapted to prevent propagation of at least one said magnetic domain wall past said first structural feature.

By providing at least one structural feature adapted to prevent propagation of at least one magnetic domain wall, this provides the advantage of making it possible to generate multiple magnetic states within different regions of a single magnetic layer. Thus, more than just two (high or low) discrete resistance values can be provided within a single MRAM cell using only one magnetic layer (i.e. ‘free layer’). This in turn increases the density of data that can be stored in, for example, a single MRAM cell.

At least one said magnetic layer may be of elongate shape having a long axis and a short axis, wherein said substantially opposite directions are substantially parallel to said long axis.

This provides the advantage of enabling the direction of propagation of a domain wall created reversal of the direction of an applied magnetic field to be more easily controlled, which in turn allows structural features to be allocated to precise locations within the magnetic layer.

At least one said magnetic layer may be shaped such that magnetic domain walls of at least one first type are only generated at one end of the magnetic layer.

This provides the advantage that the propagation characteristics of the domain wall are predictable, thus, allowing a predetermined pattern of different magnetic states in different regions of the magnetic layer to be generated.

At least one said first structural feature may be a notch in the corresponding said magnetic layer.

At least one said second structural feature may be a protrusion on the corresponding said magnetic layer.

At least one said first and/or second structural feature may be located on an edge of the corresponding said magnetic layer.

At least one third structural feature may be a localized magnetic property of a predetermined type in said magnetic layer.

According to another aspect of the present invention, there is provided a magnetic data storage device comprising at least one magnetic structure as defined above, writing means for writing data to said device, and reading means for reading data from said device.

This provides the advantage of allowing multiple bits to be stored by means of a single ‘free layer’ within a magnetoresistive random access memory (MRAM) cell, thereby minimizing the space and material needed to produce an MRAM cell with improved bit storage capacity.

The writing means may comprise means for reversing the direction of a magnetic field applied to at least one said region of a said magnetic structure.

The reading means may comprise means for measuring the electrical resistance of at least one said magnetic layer.

According to a further aspect of the present invention, there is provided a method of creating a magnetic structure having a plurality of regions, wherein the regions of each pair of adjacent said regions of said layer are magnetised predominantly along opposite directions and are separated by a respective magnetic domain wall, (i) at least one first structural feature adapted to prevent propagation of at least one said magnetic domain wall of a first type past said first structural feature, and (ii) at least one second structural feature adapted to prevent propagation of at least one said magnetic domain wall of a second type past said second structural feature, the method comprising:
providing at least a first magnetic field forming at least one magnetic domain wall of a first type;
providing an electric current causing at least said first magnetic domain wall to propagate along at least part of said layer.

The method may further comprise the step of providing at least a second magnetic field forming at least one domain wall of a second type.

At least one said structural feature may be a protrusion on said magnetic layer.

At least one said structural feature may be a notch in said magnetic layer.

At least one said structural feature may be a localized magnetic property of a predetermined type in said magnetic layer.

The magnetic field may be a result of combining at least one first magnetic field having a first field vector and/or magnitude with a second magnetic field having a second field vector and/or magnitude.

This provides the advantage that domain walls of different types can be formed using magnetic fields of different characteristics. Thus, different regions can be formed selectively within the magnetic layer by domain walls of a predetermined type that are either prevented or permitted from propagating past a structural feature of a specific type. Hence, the propagation of the domain wall is not only affected by the type of structural feature but also by the type of domain wall, therefore, adding another degree of freedom to selectively forming different regions within the magnetic layer.

### BRIEF DESCRIPTION OF THE DRAWINGS

Preferred embodiments of the present invention will now be described, by way of example only and not in any limitative sense, with reference to the accompanying drawings, in which:

FIG. 1 is a simplified perspective view of known magnetoresistive random access memory (MRAM) cell;

FIG. 2 shows a schematic representation of a magnetic structure of a first embodiment of the present invention in a magnetised state (a) before reversing the magnetic field, (b) after reversing the magnetic field in (a) generating a domain wall having a first type that is trapped at a first structural feature and (c) after reversing the magnetic field in (a) generating a domain wall having a second type that is trapped at a second structural feature;

FIG. 3 shows eight possible patterns of magnetised regions of the magnetic structure of FIG. 2;

FIG. 4 shows magnetic structures of alternative embodiments of the present invention;

FIG. 5 shows a schematic representation of a magnetoresistive random access memory (MRAM) cell embodying the present invention and including the magnetic structure of FIG. 2; and

FIG. 6 shows the relationship between typical resistance values of the magnetisation states of the magnetic structure shown in FIG. 3.

### DETAILED DESCRIPTION OF EMBODIMENTS

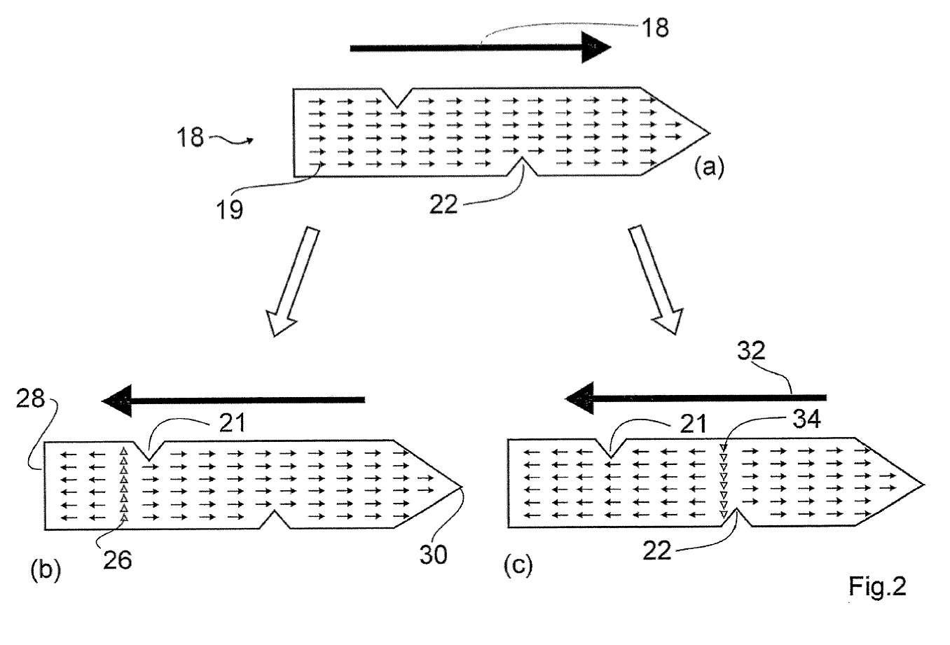

Referring to FIG. 2a, a magnetic structure embodying the present invention includes a magnetic layer 18 sufficiently thin that the magnetic moments 19 of the magnetic layer 18 are aligned substantially uniformly within the magnetic layer 16 along an external magnetic field 20. The magnetic layer 18 is of elongated shape with a long axis and a short axis. The magnetic moments 19 are predominantly aligned with the long axis. A first notch 21 and a second notch 22 are positioned asymmetrically along the long axis on opposite edges of the magnetic layer 18, respectively.

One end of the magnetic layer 18 is formed as a sharp edge in order to ensure that domain walls propagate in a first direction only.

FIG. 2b shows the magnetic layer 18 after the direction of magnetisation is reversed, by applying a magnetic field 24 or, as will be appreciated by persons skilled in the art, a spin-polarized current. A magnetic domain wall 26 having a first type is formed on the first end 28 of the magnetic layer 18, propagates towards the other end 30 and is trapped at notch 21 forming two regions having opposite magnetic moments.

FIG. 2c, on the other hand, shows the magnetic layer 18 after the direction of magnetisation is reversed by applying a magnetic field 32. A magnetic domain wall 34 having a second type is formed at the first end 28 of the magnetic layer 18 and propagates towards the other end 30. The domain wall 34 passes the first notch 21 and is trapped by the second notch 22, thus, forming two different regions having opposite magnetic moments.

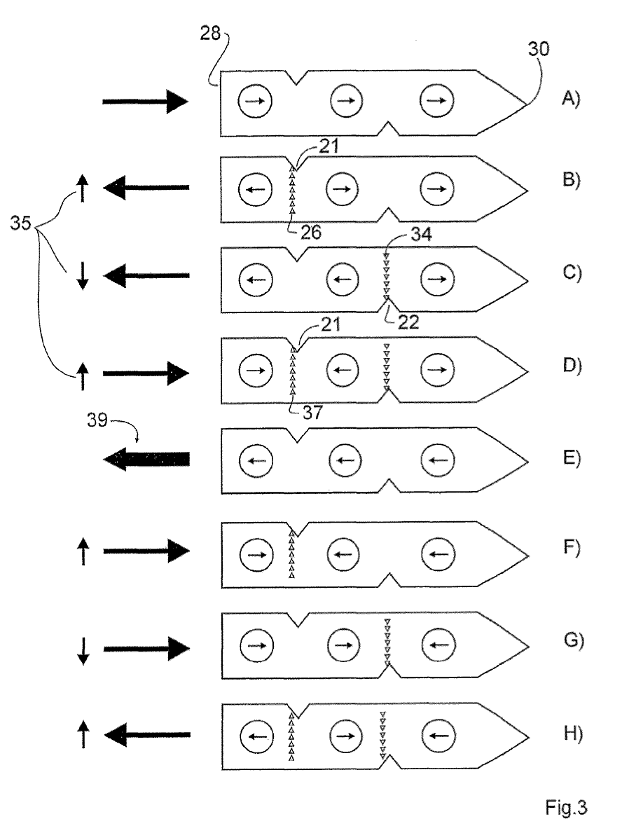

FIGS. 3A-E show eight different possible magnetisation states within the magnetic layer 18. Here, the magnetic moments of each region are represented by a single arrow. The different magnetisation states are achieved by generating domain walls of different types propagating from the first end 28 towards the other end 30. From the initial uniform magnetic state, a domain wall 26 of a first type is created and trapped at the first notch 21, or a domain wall 34 of the second type propagates past the first notch without trapping and is trapped by the second notch 22. A second domain wall of the first type can then be created and propagate to the first notch 21, where it is trapped. The domain walls 26, 34 can be removed by the application of a magnetic field stronger than a predetermined level, in order to create a uniform state of opposite magnetisation to the initial magnetisation state. From this uniform magnetic state further magnetisation states are achieved by generating domain walls as shown in FIG. 3F-H. The eight different possible magnetisation states can represent stored data, as will be described in greater detail below.

In addition, by combining magnetic fields with different field vectors, domain walls of predetermined types can be selectively formed and propagated within the magnetic layer either past a structural feature of a first type, or the domain wall is “pinned” at a structural feature of a second type preventing it from propagating any further. Domain walls of different types are, for example, transverse walls, which are differentiated by determining the direction of the wall direction, vortex walls, where the magnetisation structure within the wall forms a circular vortex that is orientated either clockwise or anti-clockwise. Other domain wall types are, for example, asymmetric transverse walls, which are defined by the direction of the magnetization within the wall, Neel walls and Bloch walls, which occur predominantly in thicker or bulk magnetic materials.

Hence, the domain wall locations and the consequent domain configuration are defined by the type of the domain walls selected and their interactions with the structural features of a specific type. Therefore, more domain wall locations, configurations and consequently more memory states can be obtained with a smaller range of magnetic field values compared to the ones used known in the prior art. Also, the maximum magnitude of the magnetic field required to write a given number of stored Bits is reduced, thus, less power is used for the writing process.

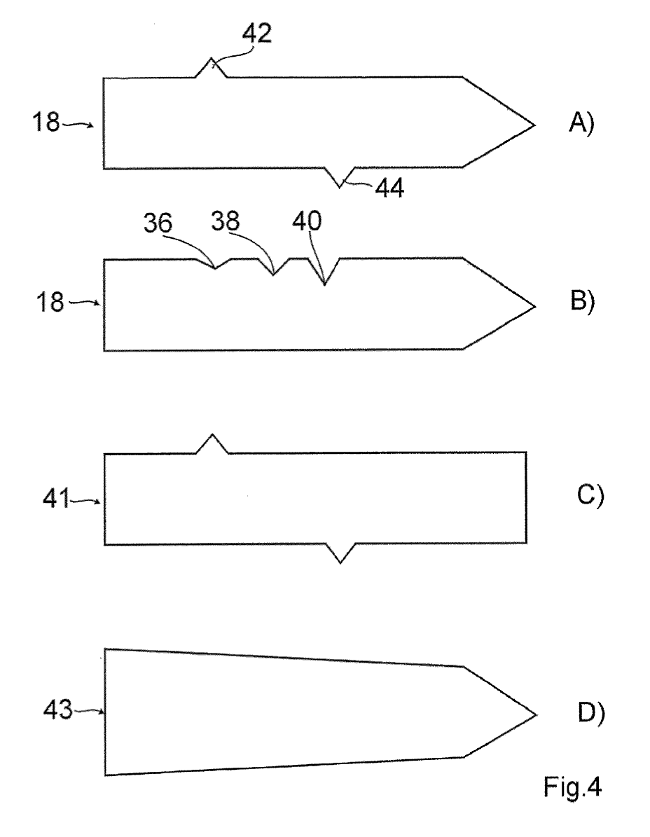

Also, further trapping structures with increasing trapping energy could increase the number of magnetisation configurations within the magnetic structure. Examples of different magnetic layer shapes and different types of structured features are shown in FIGS. 4A-D. The structured features may be notches 36, 38, 40 of different depth as shown in FIG. 4B or protrusions 42 and 44 as shown in FIG. 4A. The domain walls may also be trapped by varying width or thickness of the magnetic layer 18 as shown in FIG. 4D. Structural features can also be other local variations of the magnetic behaviour or property of the magnetic structure such that walls of different types are either prevented or allowed to propagate past the structural feature.

Geometrical structural features such as notches, protrusions or local variations in thickness may be formed using lithographic patterning techniques such as photolithography or etching. Deposition of some materials on, for example, by lithographic patterns locally exposed regions, may also be used to pin domain walls.

Local scale variations of magnetic properties may, for example, be achieved by locally introducing other atomic species by direct implantation or intermixing of layers by irradiation, e.g. a gold layer on top of the magnetic material. The localisation can be achieved by using, for example, focused ion beam irradiation such as focused gallium ions or unfocused ion irradiation such as helium on a lithographic masking.

In addition, the magnetic domain walls may be formed on either one or both ends of the magnetic layer 18. A possible shape of a magnetic layer that would allow propagation from either end is show in FIG. 4C.

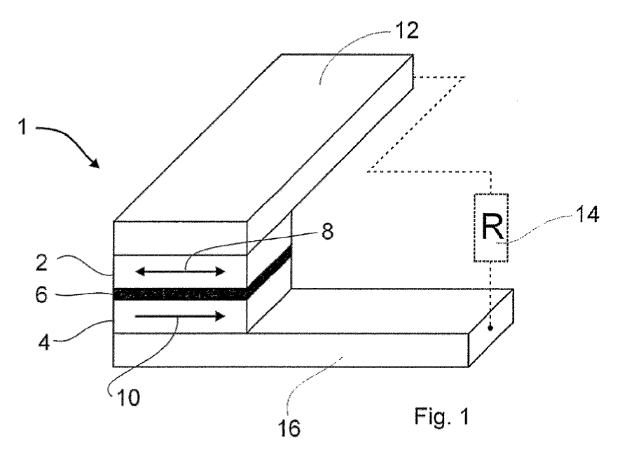

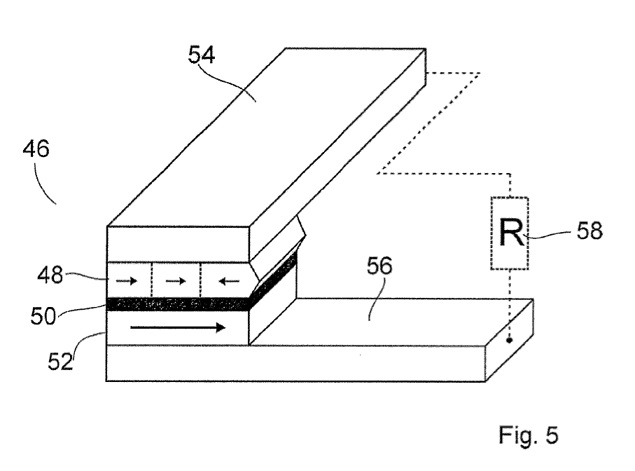

Referring to FIG. 5, an MRAM cell 46 includes a single magnetic structure 48 embodying the present invention instead of the ‘free layer’ shown in FIG. 1, a dielectric layer 50 and a ferromagnetic layer 52. A first electrode 54 is coupled to the magnetic structure and a second electrode 56 is coupled to the ferromagnetic layer 52. Multiple bits can be stored using the basic MRAM cell 46, because the magnetic structure allows the creation of multiple magnetisation states within the magnetic structure 48, each of which corresponds to a different value of the electrical resistance 58 between the first electrode 54 and the second electrode 56.

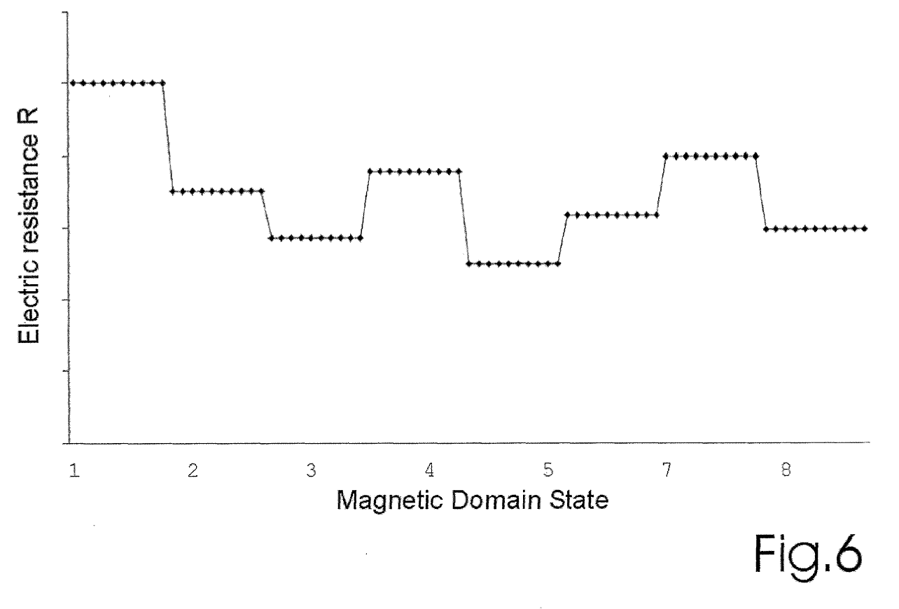

FIG. 6 shows typical relative values of the resistance 58 of the layer 52 in the various magnetic states shown in FIG. 3. It can be seen that there is sufficient difference between the resistance values to enable the various magnetisation states to be identified, which in turn enables information to be stored with a larger bit density than in known MRAM cells.

It will be appreciated by persons skilled in the art that the above embodiments have been described by way of example only, and not in any limitative sense, and that various alterations and modifications are possible without departure from the scope of the invention as defined by the appended claims. For example, although the different regions of the magnetic layer 18 are shown in the figures as having approximately equal length, it will be appreciated by persons skilled in the art that these can formed with differing lengths in order to increase the difference between the various resistance states of the magnetic structure, thus making the resistance states of the device easier to determine.

1. A magnetic structure comprising at least one magnetic layer adapted to be magnetised such that said layer includes (i) a respective plurality of regions, wherein the regions of each pair of adjacent said regions of said layer are magnetised predominantly along opposite directions and are separated by a respective magnetic domain wall, (ii) at least one first structural feature adapted to prevent propagation of at least one said magnetic domain wall of a first type past said first structural feature, and (iii) at least one second structural feature adapted to prevent propagation of at least one said magnetic domain wall of a second type past said second structural feature.

2. A structure according to claim 1, wherein at least one said magnetic layer is of elongate shape having a long axis and a short axis, wherein said substantially opposite directions are substantially parallel to said long axis.

3. A structure according to claim 1 or 2, wherein at least one said magnetic layer is shaped such that magnetic domain walls of at least one type are only generated at one end of the magnetic layer.

4. A structure according to any one of the preceding claims, wherein at least one said first structural feature is a notch in the corresponding said magnetic layer.

5. A structure according to any one of the preceding claims, wherein at least one said second structural feature is a protrusion on the corresponding said magnetic layer.

6. A structure according to any one of the preceding claims, wherein at least one third structural feature is a localized magnetic property of a predetermined type in said magnetic layer.

7. A structure according to any one of the preceding claims, wherein at least one said first and/or second and/or third structural feature is located on an edge of the corresponding said magnetic layer.

8. A magnetic data storage device comprising at least one magnetic structure according to any one of the preceding claims, writing means for writing data to said device, and reading means for reading data from said device.

9. A device according to claim 8, wherein the writing means comprises means for reversing the direction of a magnetic field applied to at least one said region of a said magnetic structure.

10. A device according to claim 8 or 9, wherein the reading means comprises means for measuring the electrical resistance of at least one said magnetic layer.

11. A method of creating a magnetic structure having a plurality of regions, wherein the regions of each pair of adjacent said regions of said layer are magnetised predominantly along opposite directions and are separated by a respective magnetic domain wall, (i) at least one first structural feature adapted to prevent propagation of at least one said magnetic domain wall of a first type past said first structural feature, and (ii) at least one second structural feature adapted to prevent propagation of at least one said magnetic domain wall of a second type past said second structural feature, the method comprising:
providing at least a first magnetic field forming at least one magnetic domain wall of a first type;
providing an electric current causing at least said first magnetic domain wall to propagate along at least part of said layer.

12. A method according to claim 11, further comprising the step of:
providing at least a second magnetic field forming at least one domain wall of a second type.

13. A method according to claim 11, wherein at least one said first structural feature is a protrusion on said magnetic layer.

14. A method according to claim 11, wherein at least one said second structural feature is a notch in said magnetic layer.

15. A method according to claim 11, wherein at least one third said structural feature is a localized magnetic property of a predetermined type in said magnetic layer.

16. A method according to any one of the preceding claims, wherein said magnetic field is a result of combining at least one first magnetic field having a first field vector and/or magnitude with a second magnetic field having a second field vector and/or magnitude.
